(19) United States
(12) Patent Application Publication
(10) Pub. No.: US 2026/0255494 A1
(43) Pub. Date: Aug. 27, 2026

(54) METHOD OF MANUFACTURING MULTILAYER PCB FOR SEMICONDUCTOR TESTING AND MULTILAYER PCB MANUFACTURED THEREBY

(71) Applicants: Young Dae KIM, Seongnam-si (KR); TES CO., LTD, Yongin-si (KR)

(72) Inventor: Young Dae KIM, Seongnam-si (KR)

(73) Assignees: Young Dae KIM, Seongnam-si (KR); TES CO., LTD, Yongin-si (KR)

(21) Appl. No.: 19/551,657

(22) Filed: Feb. 27, 2026

(30) Foreign Application Priority Data
Feb. 27, 2025 (KR) 10-2025-0026165

(51) Int. Cl. H05K 3/06; H05K 3/02; H05K 3/46; G01R 31/28

(52) U.S. Cl. CPC H05K 3/06; H05K 3/022; H05K 3/4641; G01R 31/2806; H05K 2203/0353

(57) ABSTRACT

A method of manufacturing a PCB for semiconductor testing according to one aspect of the present invention includes an operation (a) of preparing a copper clad laminate (CCL) plate in which copper foil layers serving as dummy layers are formed on both surfaces of a core layer, an operation (b) of processing a plated through hole (PTH) in the CCL plate, an operation (c) of, etching the copper foils to reduce a thickness thereof and then forming the PTH, an operation (d) of forming chemical copper on the copper foils and the PTH of an intermediate product subjected to the operation (c), an operation (e) of forming electrolytic copper, an operation (f) of forming a circuit pattern by removing the chemical copper and the remaining portions of the copper foils, and an operation (g) of repeatedly performing the operations (c) to (f) until all layers are completely formed.

### CROSS-REFERENCE TO RELATED APPLICATION(S)

This application claims priority to and the benefit of Korean Patent Application No. 10-2025-0026165, filed on 2025-02-27, the disclosure of which is incorporated herein by reference in its entirety.

### BACKGROUND

### 1. Field

The present invention relates to a method of manufacturing a multilayer printed circuit board (PCB) for semiconductor testing and a multilayer PCB manufactured thereby, and more particularly, to a method of manufacturing a multilayer PCB for semiconductor testing by which an ultra-fine circuit pattern is implemented in the multilayer PCB for semiconductor testing while a thickness thereof may be appropriately adjusted to be compatible with an existing PCB, and a multilayer PCB manufactured thereby.

### 2.Description of Related Art

As is well known, semiconductor processes are largely divided into a fabrication (Fab) process of performing fabrication using a wafer and a package process of packaging a chip formed on the wafer. After the two processes are performed, it is necessary to determine whether each of the chips is defective, and thus a test process is required for this purpose.

Meanwhile, a pitch of a printed circuit board (PCB) for semiconductor testing may be determined according to a spacing of wafer chip bonding pads in the case of wafer electric die sorting (EDS), and for example, determined according to a spacing between balls of a ball grid array (BGA) (various types of semiconductor packages other than the BGA may exist) in the case of package testing.

In the case of the PCB for semiconductor package testing, a BGA ball pitch mainly ranges from 0.3 to 1.27 mm, and a test socket used therefor also has substantially the same pitch.

When describing an existing PCB for semiconductor packaging compared to the PCB for semiconductor package testing, the existing PCB used for semiconductor packaging (generally in this case, referred to as a substrate instead of a PCB) has a thickness of 0.2 to 0.3 mm or less which is very thin, and the number of layers thereof is mainly two, and four layers are used only in a special case.

As a material of the substrate, instead of a flame retardant 4 (FR4) material used for a PCB of a general home appliance or electronic device, a bismaleimide triazine (BT) material, which has good heat resistance, has excellent bonding strength with a molding material during package manufacturing, and has excellent quality and reliability as a semiconductor package, is mainly used. On the other hand, for the PCB for semiconductor package testing, unlike the above-described substrate, FR4, high glass transition temperature FR4 (High Tg FR4), and polyimide materials are mainly used.

Meanwhile, the semiconductor package test processes may be broadly classified into a room temperature test process performed at room temperature and a burn-in test process performed at a high temperature of 125 °C or higher. Here, the burn-in test process is for testing semiconductor products under a severe condition of high temperature during production so as to remove the semiconductor products having imperfect quality in advance.

Since the burn-in test process is performed inside a high-temperature chamber in a state in which semiconductor packages are individually inserted into a burn-in board (PCB) into which a plurality of burn-in sockets are inserted, a general FR4 material having a low glass transition temperature (Tg) are not used as a material of a test PCB, and thus polyimide, BT, and High Tg FR4 materials having a high Tg are used.

Meanwhile, when describing a process of manufacturing a general PCB including the PCB for semiconductor package testing and the substrate for semiconductor packaging, in the case of the general PCB, since lines defining pattern widths of a PCB circuit and spaces defining spacings between the lines are relatively wide, the general PCB is mainly manufactured by a tenting method or a subtractive method that is a long-established conventional method.

On the other hand, the substrate for semiconductor packaging is mainly manufactured by a modified semi additive process (mSAP) or a semi additive process (SAP) because PCB lines and spaces are extremely ultra-fine compared with the above-described general PCB. The SAP process is a process for manufacturing a PCB having lines and spaces that are finer and narrower compared to the mSAP process, and the line and the space are approximately 60 µm or more in the tenting method, 40 to 60 µm in the mSAP method, and 40 µm or less in the SAP method. In a method according to the present invention, the mSAP method and the SAP method may be used, and hereinafter, a description will be provided by taking the mSAP method as an example.

Meanwhile, unlike the general PCB and the substrate for semiconductor packaging, since the PCB for semiconductor package testing requires socket pins of test sockets and connector pins to be inserted into all layers of the PCB, the PCB includes plated through holes (PTHs), has an increased thickness, and is implemented as a multilayer PCB having four to eight or more layers. Further, with the trend toward thinner, lighter, and smaller semiconductor packages, in recent years, there has been a recent demand for a PCB for package testing that has a line width and a space width of 60 µm or less, a PTH diameter of 0.125 to 0.127 mm, and a spacing between the PTHs of 0.25 to 0.30 mm. Hereinafter, the line width, the space width, and the spacing between holes, such as the PTHs, of the PCB are collectively referred to as a “circuit pitch.”

Depending on a type of a semiconductor package, a test environment, and other conditions, the semiconductor package burn-in test processes may be broadly classified into a direct test method in which a package is directly inserted into a test socket (SC) soldered to a main board and tested, and a device-under-test (DUT) board method in which a test socket assembly is manufactured and inserted into a main board connector hole, and hereinafter, a description will be provided by taking the DUT board method as an example.

FIG. 1 is a photograph showing an actual main board for semiconductor package testing using the DUT board method, and FIGS. 2A and 2B are a front perspective photograph and a rear perspective photograph, respectively, of a test socket assembly inserted into each DUT slot of the main board shown in FIG. 1.

As shown in FIG. 1, the main board for semiconductor package testing using the DUT board method may be formed of a PCB having, for example, a size of 450 mm×570 mm and a thickness of 1.2 to 2.4 mm or a size of 450 mm×550 mm and a thickness of 1.2 to 2.4 mm. On the surface of the main board, DUT slots into which a plurality of test socket assemblies as shown in FIGS. 2A and 2B are inserted are arranged at intervals in a matrix form.

The test socket assembly includes a DUT board DB formed of the PCB for semiconductor package testing and a test socket SC soldered to the DUT board DB and into which a DUT (not shown) is inserted. The DUT board may be formed of a PCB having, for example, a size of 10 mm×11 mm and a thickness of 1.2 mm, a size of 20 mm×22 mm and a thickness of 1.6 mm, a size of 20 mm×25 mm and a thickness of 2.0 mm, or a size of 30 mm×33 mm and a thickness of 1.2 mm, and a plurality of connector pins (see FIG. 2B) coupled to connector holes of the main board may be arranged side by side on a lower surface at both sides of an insertion portion of the test socket SC.

The main board for semiconductor package testing using the DUT board method has the advantage of convenience in that even when a type of a semiconductor package, which is a DUT to be tested, is changed, the main board may be left in place and only the test socket assembly may be replaced, which is convenient, and also has the advantage of easy maintenance and management since the test socket assembly is not directly soldered to the main board.

FIG. 3 is a partial cross-sectional configuration view according to an example of a multilayer PCB constituting a conventional DUT board for semiconductor package testing. As shown in FIG. 3, in the multilayer PCB constituting the conventional DUT board for semiconductor package testing, a plated through hole PTH, a non-plated through hole NPTH, or the like vertically passing through an entirety of the multilayer PCB with an inside thereof plated or non-plated may be present, and in addition thereto, various types of holes (blind vias and buried vias) formed to pass through only some layers of the multilayer PCB may be present.

FIG. 4 is a partial cross-sectional configuration view according to an example of an eight-layer PCB constituting a conventional DUT board for semiconductor package testing and shows the eight-layer PCB manufactured by a tenting method. As shown in FIG. 4, in the conventional DUT board for semiconductor package testing manufactured by the tenting method, with an insulating layer, for example, a core layer Core or a prepreg layer Prepreg, interposed between layers, signal layers Signal may be disposed on a first layer and a second layer, and a ground layer GND and a signal layer may be disposed on a third layer and a fourth layer, respectively. A power layer Power and a signal layer may be disposed on a fifth layer and a sixth layer, and a power layer and a signal layer may be disposed on a seventh layer and an eighth layer.

In the above-described configuration, the fourth layer and the fifth layer, which are intermediate layers, may be implemented as a copper clad laminate (CCL), and this CCL may be provided in advance in a state in which copper foils are laminated on upper and lower surfaces of the core layer, which is the insulating layer. In addition, the second and third layers and the sixth and seventh layers may also be implemented as a CCL provided in advance. First, copper foils of the second layer and the third layer, the fourth layer and the fifth layer, and the sixth layer and the seventh layer, which are manufactured and provided in advance in a CCL form, are appropriately patterned (to be described below) according to a purpose of each layer to form a signal layer, a power layer, and a ground layer.

In this state, prepreg is interposed between the third layer CCL and the fourth layer CCL, prepreg is interposed between the fifth layer CCL and the sixth layer CCL, and prepreg and copper foil are interposed on an upper surface of the second layer and a lower surface of the seventh layer, and then first to eighth layers are simultaneously bonded. Thereafter, signal layers of the first layer and the eighth layer may be completely formed by forming a PTH hole, forming chemical copper and electrolytic copper, and then performing patterning, and after performing a photo imageable solder resist (PSR) process for protecting a signal pattern, silk printing, gold plating, and routing processes may be performed, thereby manufacturing the DUT board for semiconductor package testing.

Meanwhile, in the DUT board for semiconductor package testing manufactured as described above, a thickness of the DUT board may be appropriately adjusted by appropriately increasing or decreasing a thickness of a core layer constituting each CCL or copper foils laminated on upper and lower surfaces thereof.

FIG. 5 is a process flowchart for describing a method of manufacturing a conventional DUT board for semiconductor package testing using a tenting method. As shown in FIG. 5, in the conventional DUT board for semiconductor package testing using the tenting method, for example, for a first layer, after forming a hole in a prepreg and a copper foil layers laminated on an upper portion of a second layer, in a state in which a chemical copper layer functioning as a seed is thinly formed by an electroless plating method, an electrolytic copper layer having a desired thickness is formed thereon by an electroplating method. In this state, after forming a photo image using a dry film on the electrolytic copper layer, a desired pattern may be formed in the copper foil and electrolytic copper layers through development–etching–stripping processes, thereby completing a circuit pattern for the first layer.

Since the copper foil is already laminated in the respective CCLs constituting the second layer and the third layer, the fourth layer and the fifth layer, and the sixth layer and the seventh layer, the circuit pattern for the corresponding layer may be completely formed starting from a process of forming a photo image using a dry film.

FIGS. 6A and 6B are a photograph and a cross-sectional view, respectively, showing a circuit pattern formed by the method of manufacturing a conventional DUT board for semiconductor package testing using the tenting method. FIG. 7 is a view for describing problems of the conventional DUT board for semiconductor package testing manufactured using the tenting method. As shown in FIG. 6, in the conventional DUT board for semiconductor package testing manufactured using the tenting method, since a signal line pattern has a substantially trapezoidal shape having a thicker bottom and a thinner top due to an undercut during etching, there is a limitation in reducing a pitch of a line or a space to 60 µm or less. Accordingly, when an ultra-fine circuit pattern of 60 µm or less is required, as illustrated in FIG. 7, since a width of a signal line SL is greater than a spacing between PTHs, the signal line may not be disposed between the PTHs, and as a result, there is a problem in that a multilayer PCB for semiconductor package testing having an ultra-fine circuit pattern may not be provided.

Examples of related art include Korean Patent Laid-Open Publication No. 10-1998-0022345 (Title of the Invention: Printed Circuit Board for Manufacturing BGA Semiconductor Package Capable of Electrical Testing), Korean Patent Laid-Open Publication No. 10-2023-0038559 (Title of the Invention: Method for Manufacturing Package Substrate), and Korean Patent Laid-Open Publication No. 10-2017-0132628 (Title of the Invention: Semiconductor Package Test Socket)

### SUMMARY

This summary is provided to introduce a selection of concepts in a simplified form that are further described below in the Detailed Description. This summary is not intended to identify key features or essential features of the claimed subject matter, nor is it intended to be used as an aid in determining the scope of the claimed subject matter.

The present invention has been devised to solve the above-described problems, and an object thereof is to provide a method of manufacturing a multilayer printed circuit board (PCB) for semiconductor testing by which an ultra-fine circuit pattern is implemented in the multilayer PCB for semiconductor testing while a thickness thereof may be appropriately adjusted to be compatible with an existing PCB, and a multilayer PCB manufactured thereby.

In order to achieve the above-described object, according to one aspect of the present invention, a method of manufacturing a multilayer PCB for semiconductor testing includes an operation (a) of preparing a copper clad laminate (CCL) plate in which copper foil layers serving as dummy layers are formed on both surfaces of a core layer, an operation (b) of processing a plated through hole (PTH) hole in the CCL plate, an operation (c) of, in a state in which copper foils are laminated on upper and lower layers of the CCL plate with prepreg interposed therebetween, etching the copper foils to reduce a thickness thereof and then forming the PTH hole, an operation (d) of forming chemical copper on the copper foils and the PTH hole of an intermediate product subjected to the operation (c), an operation (e) of forming electrolytic copper in a state in which a photo resist image is formed using a dry film, and forming the PTH during the forming of the electrolytic copper, an operation (f) of forming a circuit pattern by removing the chemical copper and the remaining portions of the copper foils by etching after stripping the dry film, and an operation (g) of repeatedly performing the operations (c) to (f) until all layers are completely formed.

According to another aspect of the present invention, a method of manufacturing a multilayer PCB for semiconductor testing includes an operation (h) of preparing a CCL plate in which copper foil layers serving as dummy layers are formed on both surfaces of a core layer, an operation (i) of processing a PTH hole in the CCL plate, an operation (j) of forming a plurality of fine pads around the PTH hole, an operation (k) of, in a state in which copper foils are laminated on upper and lower layers of the CCL plate with prepreg interposed therebetween, etching the copper foils to reduce a thickness thereof and then forming the PTH hole and a fine hole, an operation (l) of forming chemical copper on the copper foils of an intermediate product subjected to the operation (k), an operation (m) of forming electrolytic copper in a state in which a photo resist image is formed using a dry film and forming the PTH and a fine pillar during the forming of the electrolytic copper, an operation (n) of forming a circuit pattern by removing the chemical copper and the remaining portions of the copper foils by etching after stripping the dry film, and an operation (o) of repeatedly performing the operations (k) to (n) until all layers are completely formed.

In the above-described configuration, the fine pads formed in the operation (j) are formed by forming a plurality of fine holes along a concentric circle around the PTH hole, copper-plating wall surfaces of the fine holes, filling the copper-plated fine holes with a filler of a resin material, and then performing copper plating.

The number of dummy layers is two or more.

A thickness of a core of the dummy layer is adjusted to be compatible with an existing multilayer PCB.

The multilayer PCB is a multilayer PCB for semiconductor package testing.

The multilayer PCB is a PCB for a device-under-test (DUT) board or a PCB for a main board.

Other features and aspects will be apparent from the following detailed description, the drawings, and the claims.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a photograph showing an actual main board for semiconductor package testing using a device under test (DUT) board method;

FIGS. 2A and 2B are a front perspective photograph and a rear perspective photograph, respectively, of a test socket assembly inserted into each DUT slot of a main board;

FIG. 3 is a partial cross-sectional configuration view according to an example of a multilayer printed circuit board (PCB) constituting a conventional DUT board for semiconductor package testing;

FIG. 4 is a partial cross-sectional configuration view according to an example of an eight-layer PCB constituting a conventional DUT board for semiconductor package testing;

FIG. 5 is a process flowchart for describing a method of manufacturing a DUT board for semiconductor package testing using a conventional tenting method;

FIGS. 6A and 6B are a photograph and a cross-sectional view, respectively, showing a circuit pattern formed by a method of manufacturing a DUT board for semiconductor package testing using a conventional tenting method;

FIG. 7 is a view for describing problems of a DUT board for semiconductor package testing manufactured using a conventional tenting method;

FIG. 8 is a process flowchart for describing a modified semi additive process (mSAP) method applicable to manufacturing a multilayer PCB for semiconductor testing of the present invention;

FIGS. 9A and 9B are a photograph and a cross-sectional view, respectively, showing a circuit pattern formed by a method of manufacturing a DUT board for semiconductor package testing using an mSAP method;

FIG. 10 is a partial cross-sectional configuration view according to an example of a ten-layer PCB constituting a DUT board for semiconductor package testing of the present invention;

FIG. 11 is a process flowchart for describing a method of manufacturing a DUT board for semiconductor package testing of the present invention;

FIG. 12 is a process flowchart for describing a method of manufacturing a DUT board for semiconductor package testing according to another embodiment of the present invention;

FIG. 13 is a schematic longitudinal cross-sectional view of a multilayer PCB manufactured according to the embodiment of FIG. 12;

FIG. 14 is a detailed longitudinal cross-sectional view of fine pillars in FIG. 13;

FIG. 15 is a transverse cross-sectional view showing a PTH and fine pillars in FIG. 14; and

FIG. 16 is a schematic cross-sectional view for describing a thickness ratio of a dummy layer and remaining layers in a multilayer PCB manufactured by the method of manufacturing a multilayer PCB for semiconductor testing of the present invention;

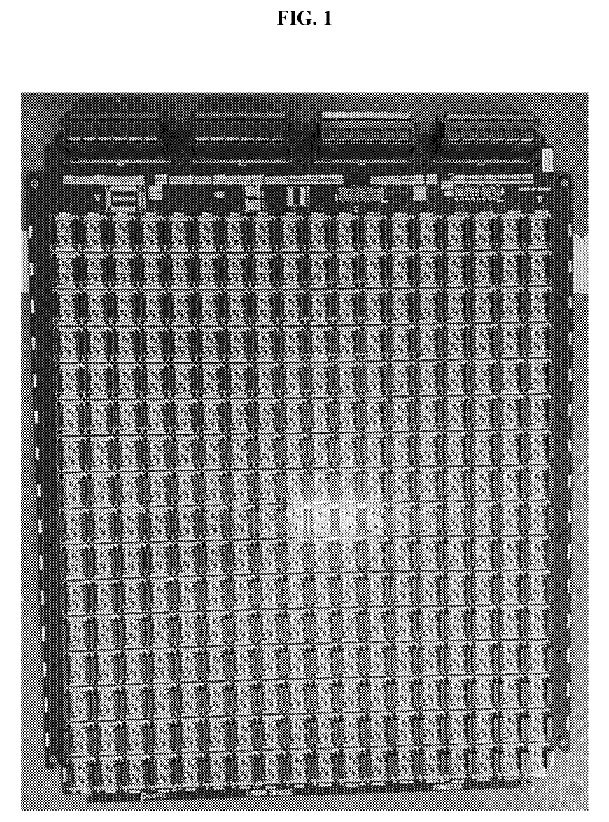

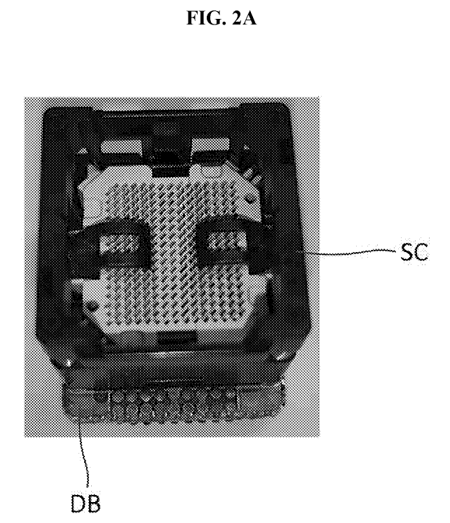

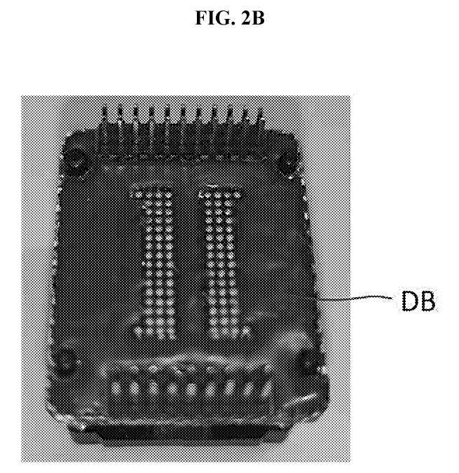

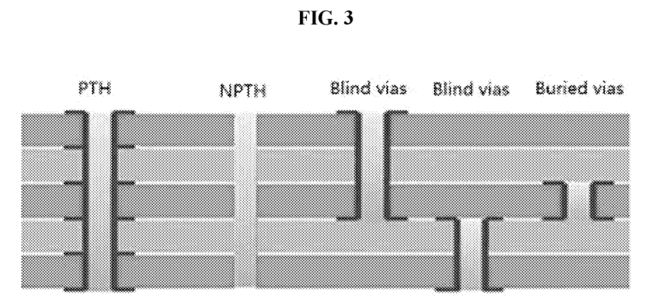

### DETAILED DESCRIPTION

Below, exemplary embodiments of a method of manufacturing a multilayer printed circuit board (PCB) for semiconductor testing of the present invention will be described in detail with reference to the accompanying drawings, and detailed descriptions of known functions and configurations that may unnecessarily obscure the gist of the invention are omitted. Further, since embodiments of the present invention are provided to more completely describe the present invention to a person having ordinary skill in the art, shapes, sizes, and the like of elements in the drawings may be exaggerated for clearer description.

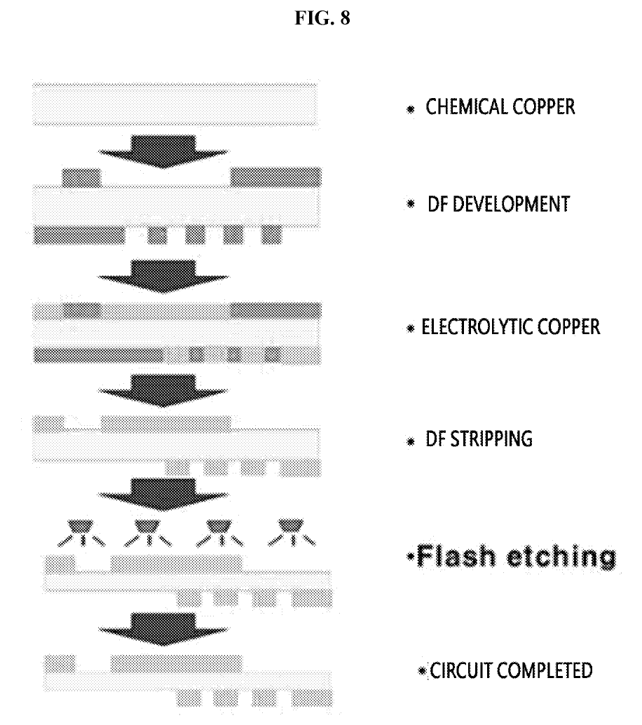

FIG. 8 is a process flowchart for describing a modified semi additive process (mSAP) method applicable to manufacturing the multilayer PCB for semiconductor package testing of the present invention. As shown in FIG. 8, according to the mSAP method applicable to manufacturing the multilayer PCB for semiconductor package testing of the present invention, first, in a state in which a chemical copper layer functioning as a seed is thinly formed on copper foil on a core layer by an electroless plating method, a photo resist is formed using a dry film, and then an electrolytic copper layer to be a circuit pattern is formed again by an electroplating method, thereby forming the electrolytic copper layer only on an upper portion of chemical copper in a portion without having the photo resist.

Next, after stripping the dry film used as the photo resist, rapid etching is performed by a flash etching method to remove the chemical copper existing under the photo resist and a copper foil layer remaining thereunder, thereby completing an ultra-fine circuit having a pitch of 40 to 60 µm.

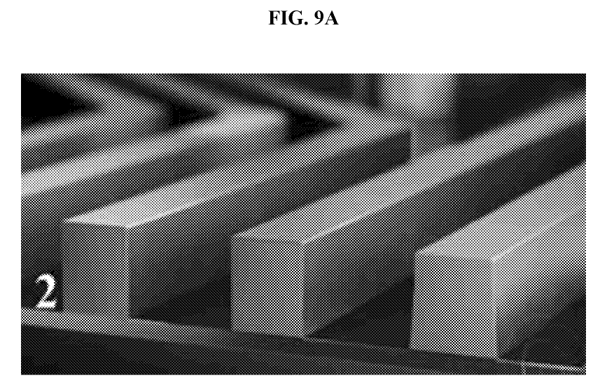

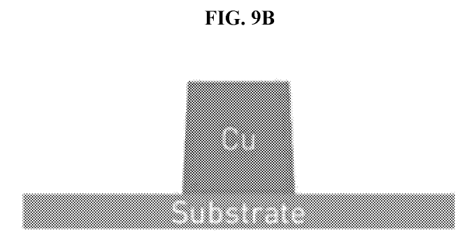

FIGS. 9A and 9B are a photograph and a cross-sectional view, respectively, showing a circuit pattern formed by a method of manufacturing a DUT board for semiconductor package testing using the mSAP method. As shown in FIG. 9, in the DUT board for semiconductor package testing manufactured by the mSAP method, a relatively sharp square-shaped signal line pattern may be formed by rapid etching using a flash etching method as compared with a tenting method, and as a result, a pitch of a line or a space may be reduced to 40 to 60 µm or less.

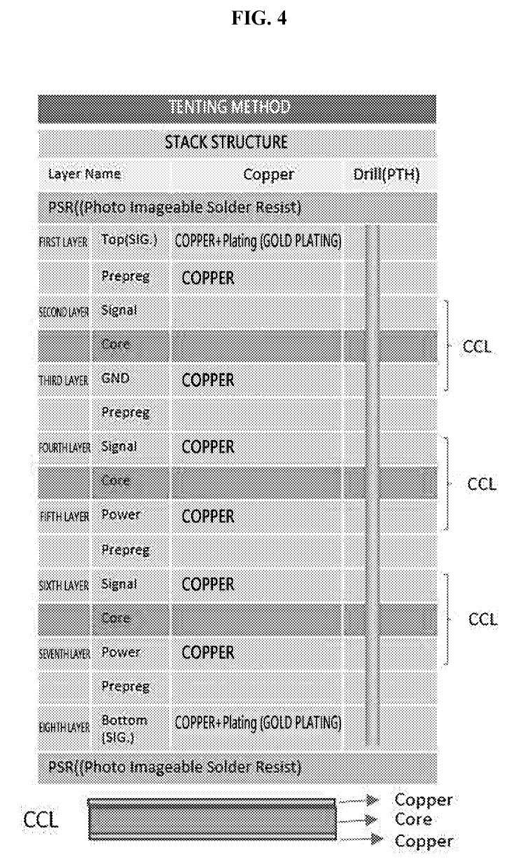

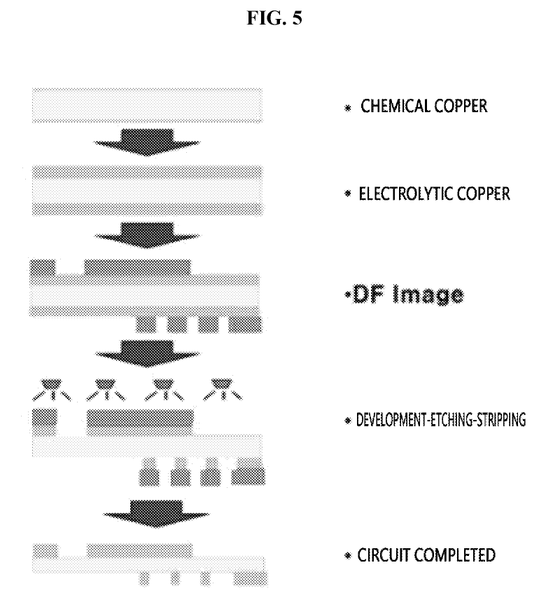

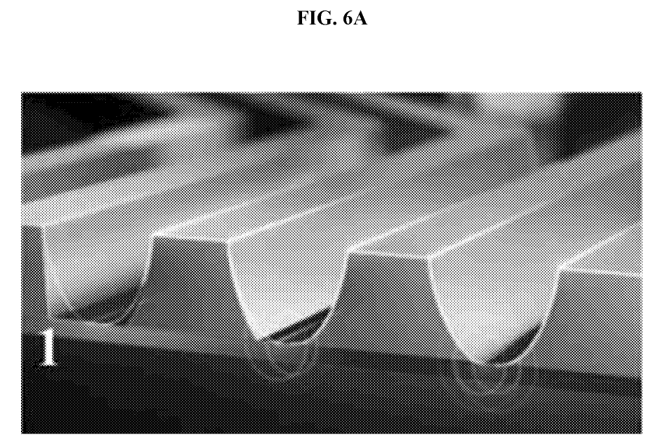

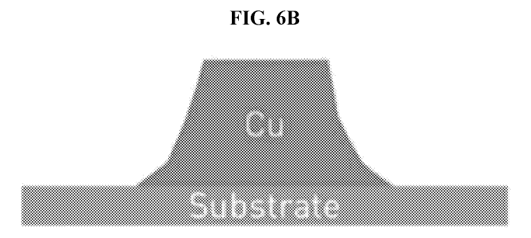

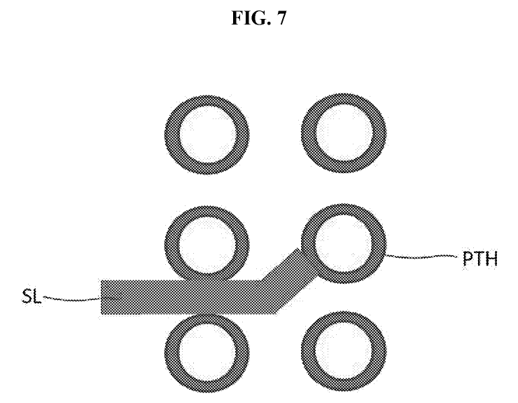

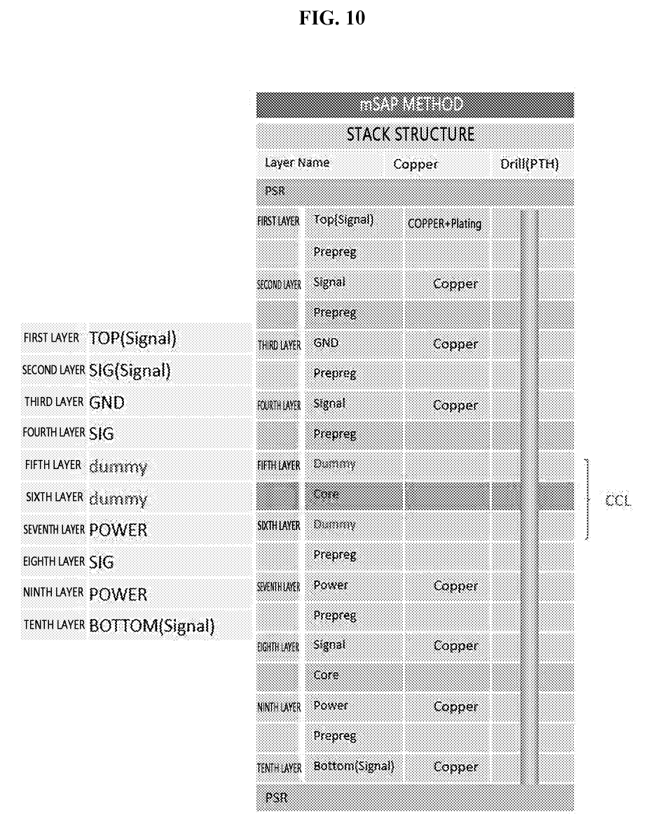

FIG. 10 is a partial cross-sectional configuration view according to an example of a ten-layer PCB constituting a DUT board for semiconductor package testing of the present invention, and illustrates a PCB having a total of ten layers in which the fifth and sixth layers functioning as dummy layers are additionally inserted below the fourth layer of the eight-layer PCB shown in FIG. 4.

In addition, similar to the eight-layer PCB shown in FIG. 4, in a state in which an insulating layer, for example, a core layer or a prepreg layer, is interposed between layers, signal layers may be disposed on a first layer and a second layer and a ground layer GND and a signal layer may be disposed on a third layer and a fourth layer, respectively. However, unlike the eight-layer PCB shown in FIG. 4, in a fifth layer and a sixth layer of the PCB manufactured by the method of the present invention, dummy layers formed of copper foil layers are interposed with the core layer interposed therebetween. Accordingly, a power layer and a signal layer may be disposed on a seventh layer and an eighth layer, and a power layer and a signal layer may be disposed on a ninth layer and a tenth layer.

In the above-described configuration, the fifth layer and the sixth layer, which are dummy layers, may be provided in advance as being implemented as a CCL. Further, by appropriately adjusting a thickness of the core layer of the CCL, a thickness of the ten-layer PCB manufactured by the method of the present invention may be made the same as a thickness of the eight-layer PCB shown in FIG. 4, and accordingly, existing semiconductor package test equipment may be used as it is. Of course, in addition to the core layer, by adjusting a thickness of copper foil layers of the fifth layer and the sixth layer provided as dummy layers together with the thickness of the core layer, an overall thickness of the ten-layer PCB may be made the same as the thickness of the eight-layer PCB shown in FIG. 4.

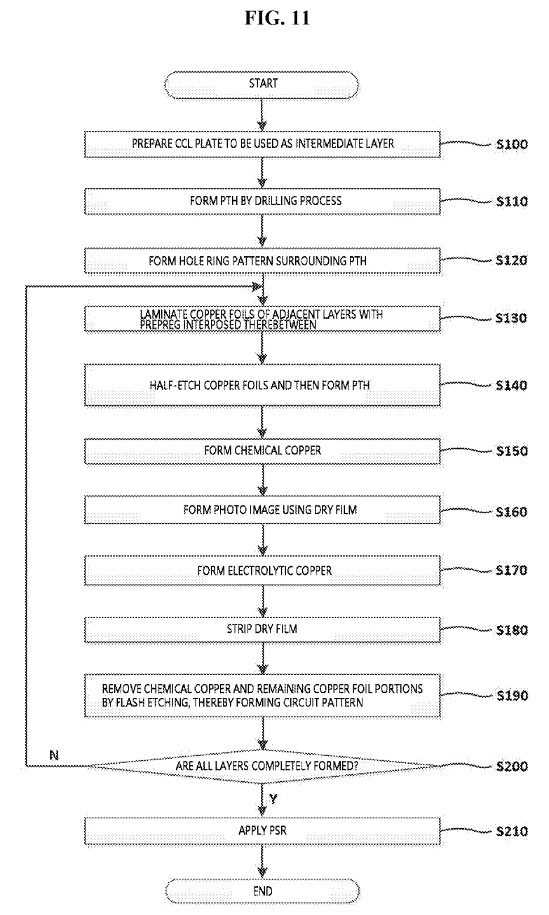

FIG. 11 is a process flowchart for describing a method of manufacturing a DUT board for semiconductor package testing according to one embodiment of the present invention. As shown in FIG. 11, according to the method of manufacturing a DUT board for semiconductor package testing according to one embodiment of the present invention, first, in operation S100, a CCL plate to be used as an intermediate layer, that is, a CCL plate manufactured by laminating copper foil layers serving as dummy layers on both surfaces of a core layer, for example, the fifth layer and the sixth layer in FIG. 10, may be prepared, and this prepared CCL plate may be manufactured to have a desired thickness by adjusting a thickness of the core layer or the copper foil layers.

Next, in operation S110, for example, through a drilling process (or a laser processing process), a hole to be used as a PTH (including an NPTH) (hereinafter referred to as a PTH hole) is drilled in the CCL plate, and in a subsequent operation S120, a hole ring pattern is formed around the PTH hole.

Next, in operation S130, in a state in which copper foils are laminated on upper and lower layers of the CCL plate with prepreg interposed therebetween, bonding is performed by a hot press method, and in a subsequent operation S140, the copper foil layers are etched again to appropriately reduce a thickness thereof, for example, to about half, and in this state, the PTH hole is formed, for example, by a drilling process (or a laser processing process).

Next, in operation S150, chemical copper is formed on the copper foil layers of the intermediate product manufactured as described above, and in this process, a wall surface of the hole formed in operations S110 and S140 is plated to form the PTH.

Next, in operation S160, a photo resist image is formed using a dry film, and in a subsequent operation S170, electrolytic copper is formed on the intermediate product subjected to operation S160, so that the electrolytic copper is formed only on a portion of the chemical copper in which the photo resist formed in operation S160 is not present.

Next, in operation S180, the dry film is stripped, and in a subsequent operation S190, chemical copper and copper foil portions remaining thereunder are rapidly etched and removed by flash etching, thereby forming an ultra-fine circuit pattern having a pitch of 40 to 60 µm. Next, in operation S200, a determination as to whether all layers (for example, a total of ten layers in FIG. 10) are completed is made, and when all layers are not completed, operations S130 and subsequent operations are repeatedly performed on the intermediate product progressed so far, and when all layers are completed, the process proceeds to operation S210 to apply a photo imageable solder resist (PSR) and end the process.

Meanwhile, according to the above-described embodiment, in the flash etching process in operation S190, there may occur a problem in that PTH plating is melted and disconnected, and in order to prevent this, by additionally providing a plurality of fine plating pillars around the PTH, all layers of the multilayer PCB may be electrically connected.

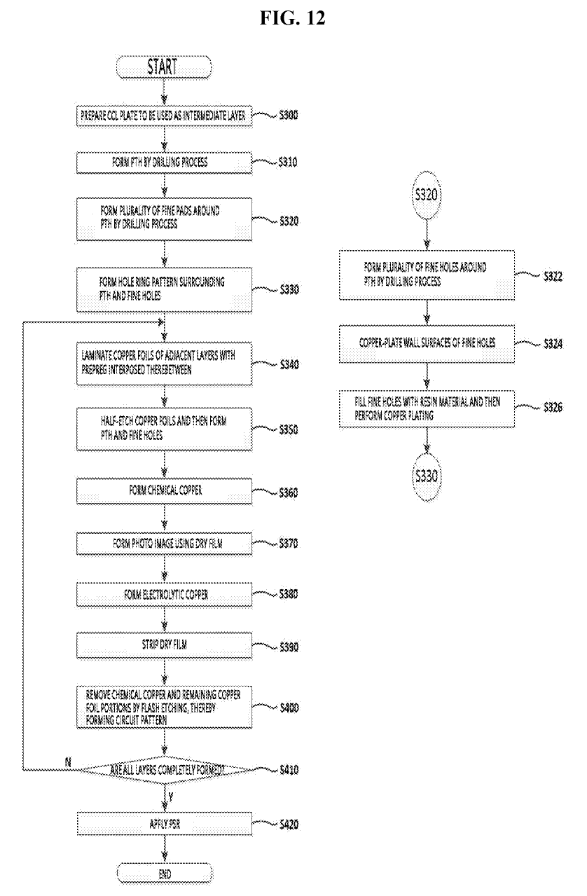

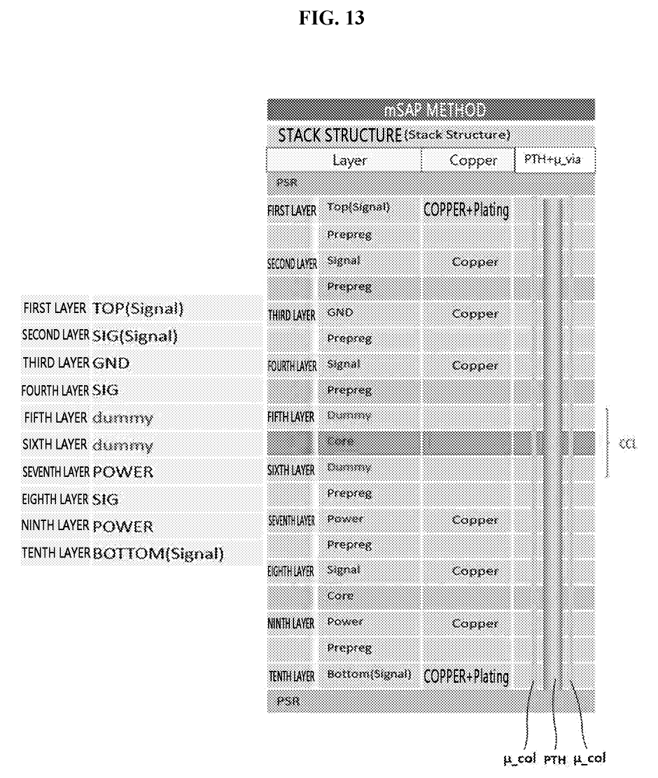

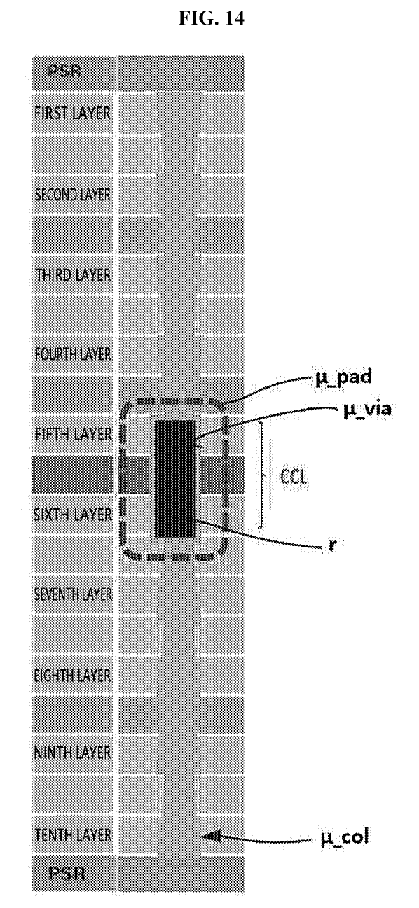

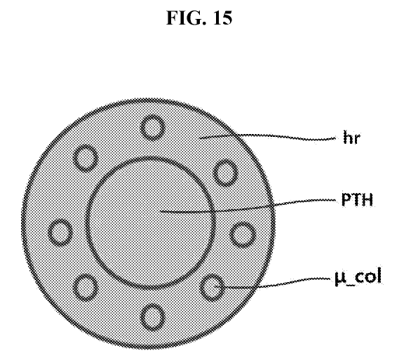

FIG. 12 is a process flowchart for describing a method of manufacturing a DUT board for semiconductor package testing according to another embodiment of the present invention. FIG. 13 is a schematic longitudinal cross-sectional view of a multilayer PCB manufactured according to the embodiment of FIG. 12, FIG. 14 is a detailed longitudinal cross-sectional view of fine pillars in FIG. 13, and FIG. 15 is a transverse cross-sectional view showing a PTH and fine pillars in FIG. 14.

First, as shown in FIG. 12, in operation S300, a CCL plate to be used as an intermediate layer, that is, a CCL plate manufactured by laminating copper foil layers serving as dummy layers on both surfaces of a core layer, for example, the fifth layer and the sixth layer in FIG. 10, may be prepared, and this prepared CCL plate may be manufactured to have a desired thickness by adjusting a thickness of the core layer or the copper foil layers.

Next, in operation S310, for example, through a drilling process (or a laser processing process), a PTH hole to be used as a PTH (including an NPTH) is drilled in the CCL plate, and in operation S320, a plurality of fine pads μ_pad of, for example, two or more are formed on a concentric circle around the PTH hole formed in the previous operation (S310) (see FIGS. 13 to 15). In detail, fine pads μ_pad may be formed by forming a plurality of fine holes μ_via, for example, fine holes μ_via in a diameter range of 10 to 150 µm, around the PTH hole by a drilling process (or a laser processing process) (operation S322), copper-plating wall surfaces of the fine holes μ_via (operation S324), and finally filling the copper-plated fine holes μ_via with a filler r of a resin material and then performing copper plating (operation S326).

Referring again to FIG. 12, in operation S330, a hole ring pattern hr surrounding the PTH hole and the fine pads μ_pad (in subsequent layers, the fine holes μ_via) is formed (see FIG. 15).

Next, in operation S340, in a state in which copper foils are laminated on upper and lower layers of the CCL plate with prepreg interposed therebetween, bonding is performed by a hot press method, and in a subsequent operation S350, the copper foil layers are etched again to appropriately reduce a thickness thereof, for example, to about half, and, in this state, the PTH hole and fine holes are formed in alignment with the PTH hole and the fine pads formed in the previous operations (S310 and S320), for example, by a drilling process (or a laser processing process).

Next, in operation S360, chemical copper is formed on the copper foil layers of the intermediate product manufactured as described above.

Next, in operation S370, a photo resist image is formed using a dry film, and in a subsequent operation S380, electrolytic copper is formed on the intermediate product subjected to operation S370, so that electrolytic copper is formed only on the portion of the chemical copper in which the photo resist formed in operation S370 is not present, and in this process, the interiors of the PTH hole and fine holes formed in operations S310, S320, and S350 are plated to form the PTH and fine pillars μ_col.

Next, in operation S390, the dry film is stripped, and in a subsequent operation S400, chemical copper and copper foil portions remaining thereunder are rapidly etched and removed by flash etching, thereby forming an ultra-fine circuit pattern having a pitch of 40 to 60 µm. Next, in operation S410, a determination is made as to whether all layers (for example, a total of ten layers in FIG. 10) are completely formed, and when all layers are not completely formed, operations S340 and subsequent operations are repeatedly performed on the intermediate product progressed so far, and when all layers are completely formed, the process proceeds to operation S420 to apply a photo imageable solder resist (PSR) and end the process.

According to the above-described embodiment, even when PTH plating is disconnected due to etching excessively performed in the flash etching process of operation S400, electrical connection may be secured by a plurality of fine pillars μ_col. In addition, the plurality of fine pillars around the PTH have an effect of solving thermal problems emerging as a semiconductor becomes faster, more complex, and highly functional.

As described above, according to the method of manufacturing a multilayer PCB for semiconductor package testing of the present invention, by using the CCL plate as the dummy layer to appropriately adjust the thickness thereof, thickness compatibility with an existing multilayer PCB may be achieved, and in addition, by performing patterning for remaining layers by the mSAP method instead of a conventional tenting method, the circuit pitch of a signal layer, a ground layer, and a power layer may be reduced, for example, to 60 µm or less.

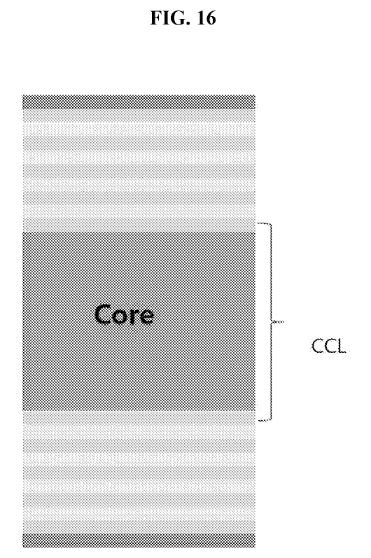

FIG. 16 is a schematic cross-sectional view for describing a thickness ratio between a dummy layer and remaining layers in a multilayer PCB manufactured by the method of manufacturing a multilayer PCB for semiconductor testing of the present invention, and a description will be provided by taking the multilayer PCB shown in FIG. 10 as an example. As shown in FIG. 16, a thickness of a core layer interposed between dummy layers of a fifth layer and a sixth layer may be determined to be approximately between 40% and 60% compared with a thickness of all remaining layers.

The method of manufacturing a multilayer PCB for semiconductor testing of the present invention and the multilayer PCB manufactured thereby are not limited to the above-described embodiments and may be variously modified and implemented within a scope permitted by the technical idea of the present invention. Therefore, a true scope of protection of the present invention should be determined only by the appended claims.

That is, in the above-described embodiments, the multilayer PCB for semiconductor package testing has been described as an example, but the present invention is not limited thereto and may also be applicable to a wafer electric die sorting (EDS) test.

Further, the multilayer PCB for semiconductor testing of the present invention is formed of an even number of layers of four layers or more, and the use of each layer may appropriately change depending on a use of the corresponding semiconductor.

In addition, unlike the above-described embodiments, the method of manufacturing a multilayer PCB of the present invention may be applicable not only to a DUT board but also to a main board using a direct test method in which a test socket assembly is directly soldered.

Further, by using the conventional tenting method, in addition to the PTH ring pattern, an appropriate circuit pattern may be formed also on the dummy layer, and when necessary for thickness adjustment and the like, more than two dummy layers may be formed.

Further, the method of manufacturing a multilayer PCB for semiconductor testing of the present invention may be performed by an SAP method in addition to the mSAP method of the above-described embodiments.

According to a method of manufacturing a PCB for semiconductor testing according to the present invention, a multilayer PCB can be implemented using an mSAP method for a signal layer and the like requiring an ultra-fine circuit pitch, and a thickness thereof can be adjusted through a dummy layer implemented using a conventional tenting method, thereby enabling thickness compatibility with an existing PCB for semiconductor testing.

Further, by forming fine pillars around a PTH, even when PTH plating is disconnected during a flash etching process, electrical connection can be secured through the fine pillars. Further, the fine pillars around the PTH have an effect of solving thermal problems emerging as a semiconductor becomes faster, more complex, and highly functional.

A number of examples have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A method of manufacturing a multilayer printed circuit board (PCB) for semiconductor testing, comprising:
an operation (a) of preparing a copper clad laminate (CCL) plate in which copper foil layers serving as dummy layers are formed on both surfaces of a core layer;
an operation (b) of processing a plated through hole (PTH) in the CCL plate;
an operation (c) of, in a state in which copper foils are laminated on upper and lower layers of the CCL plate with prepreg interposed therebetween, etching the copper foils to reduce a thickness thereof and then forming the PTH;
an operation (d) of forming chemical copper on the copper foils and the PTH of an intermediate product subjected to the operation (c);
an operation (e) of forming electrolytic copper in a state in which a photo resist image is formed using a dry film and forming the PTH during the forming of the electrolytic copper;
an operation (f) of forming a circuit pattern by removing the chemical copper and the remaining portions of the copper foils by etching after stripping the dry film; and
an operation (g) of repeatedly performing the operations (c) to (f) until all layers are completely formed.

2. A method of manufacturing a multilayer printed circuit board (PCB) for semiconductor testing, comprising:
an operation (h) of preparing a copper clad laminate (CCL) plate in which copper foil layers serving as dummy layers are formed on both surfaces of a core layer;
an operation (i) of processing a plated through hole (PTH) in the CCL plate;
an operation (j) of forming a plurality of fine pads around the PTH;
an operation (k) of, in a state in which copper foils are laminated on upper and lower layers of the CCL plate with prepreg interposed therebetween, etching the copper foils to reduce a thickness thereof and then forming the PTH and a fine hole;
an operation (l) of forming chemical copper on the copper foils of an intermediate product subjected to the operation (k);
an operation (m) of forming electrolytic copper in a state in which a photo resist image is formed using a dry film and forming the PTH and a fine pillar during the forming of the electrolytic copper;
an operation (n) of forming a circuit pattern by removing the chemical copper and the remaining portions of the copper foils by etching after stripping the dry film; and
an operation (o) of repeatedly performing the operations (k) to (n) until all layers are completely formed.

3. The method of claim 2, wherein the fine pads formed in the operation (j) are formed by forming a plurality of fine holes along a concentric circle around the PTH, copper-plating wall surfaces of the fine holes, filling the copper-plated fine holes with a filler of a resin material, and then performing copper plating.

4. The method of claim 1, wherein the number of dummy layers is two or more.

5. The method of claim 4, wherein a thickness of a core of the dummy layer is adjusted to be compatible with an existing multilayer PCB.

6. The method of claim 5, wherein the multilayer PCB is a multilayer PCB for semiconductor package testing.

7. The method of claim 6, wherein the multilayer PCB is a PCB for a device-under-test (DUT) board or a PCB for a main board.

8. A multilayer printed circuit board (PCB) for semiconductor testing manufactured by the method of claim 1.

9. The method of claim 2, wherein the number of dummy layers is two or more.

10. A multilayer printed circuit board (PCB) for semiconductor testing manufactured by the method of claim 2.
